(19) United States
(12) Patent Application Publication
(10) Pub. No.: US 2018/0115302 A1
(43) Pub. Date: Apr. 26, 2018

(54) BULK ACOUSTIC WAVE RESONATORS HAVING DOPED PIEZOELECTRIC MATERIAL AND A BUFFER LAYER

(71) Applicant: Avago Technologies General IP (Singapore) Pte. Ltd., Singapore (SG)

(72) Inventors: Tangshiun Yeh, Fort Collins, CO (US); Ryan Pooran, Loveland, CO (US); David Martin, Fort Collins, CO (US)

(21) Appl. No.: 15/335,402

(22) Filed: Oct. 26, 2016

(51) Int. Cl. H03H 9/17

(52) U.S. Cl. CPC H03H 9/171

(57) ABSTRACT

BAW resonators comprise a first electrode; a second electrode; and a piezoelectric layer disposed between the first and second electrodes. The piezoelectric layer comprises a piezoelectric material doped to a minimum atomic percentage with at least one rare earth element. In a representative embodiment, the BAW resonators comprise a first buffer layer disposed over the first electrode; and a second buffer layer disposed over the first piezoelectric layer. In a representative embodiment, the first buffer layer, or the second buffer layer, or both, are doped with the at least one rare earth element to an atomic percentage that is less than the minimum percentage.

### BACKGROUND

Acoustic resonators can be used to implement signal processing functions in various electronic applications. For example, some cellular phones and other communication devices use acoustic resonators to implement frequency filters for transmitted and/or received signals. Several different types of acoustic resonators can be used according to different applications, with examples including bulk acoustic wave (BAW) resonators such as thin film bulk acoustic resonators (FBARs), solidly mounted resonators (SMRs), coupled resonator filters (CRFs), stacked bulk acoustic resonators (SBARs) and double bulk acoustic resonators (DBARs).

A typical acoustic resonator comprises a layer of piezoelectric material sandwiched between two plate electrodes in a structure referred to as an acoustic stack. Where an input electrical signal is applied between the electrodes, reciprocal or inverse piezoelectric effect causes the acoustic stack to mechanically expand or contract depending on the polarization of the piezoelectric material. As the input electrical signal varies over time, expansion and contraction of the acoustic stack produces acoustic waves that propagate through the acoustic resonator in various directions and are converted into an output electrical signal by the piezoelectric effect. Some of the acoustic waves achieve resonance across the acoustic stack, with the resonant frequency being determined by factors such as the materials, dimensions, and operating conditions of the acoustic stack. These and other mechanical characteristics of the acoustic resonator determine its frequency response.

One metric used to evaluate the performance of an acoustic resonator is its electromechanical coupling coefficient (kt²), which indicates the efficiency of energy transfer between the electrodes and the piezoelectric material. Other things being equal, an acoustic resonator with higher kt² is generally considered to have superior performance to an acoustic resonator with lower kt². Accordingly, it is generally desirable to use acoustic resonators with higher levels of kt² in high performance wireless applications, such as 4G and LTE applications.

The kt² of an acoustic resonator is influenced by several factors, such as the dimensions, composition, and structural properties of the piezoelectric material and electrodes. These factors, in turn, are influenced by the materials and manufacturing processes used to produce the acoustic resonator. Consequently, in an ongoing effort to produce acoustic resonators with higher levels of kt², researchers are seeking improved approaches to the design and manufacture of acoustic resonators.

One method that is useful in improving the kt² of piezoelectric materials is by doping the piezoelectric material with a selected dopant, such as a rare-earth element. While doping the piezoelectric material can provide improvement in kt², in applications in BAW resonators, in known structures, as the atomic percentage of certain dopants is increased in an effort to further increase kt², certain undesired results occur. Just by way of example, in certain structures, increasing the atomic percentage of certain dopants results in an unacceptable degree of variation of kt² over the doped piezoelectric layer. Such variations can cause tolerance issues in large scale manufacturing, reducing the overall yield of the manufacturing process.

What is needed, therefore, is a BAW resonator that overcomes at least the shortcomings of known BAW resonators described above.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1A is a top view of a BAW resonator in accordance with a representative embodiment.

FIG. 1B is a cross-sectional view of a BAW resonator according to a representative embodiment.

FIG. 1C is a cross-sectional view of a BAW resonator according to a representative embodiment.

FIG. 2A is a cross-sectional view of a BAW resonator according to a representative embodiment.

FIG. 2B is a cross-sectional view of a BAW resonator according to a representative embodiment.

### DETAILED DESCRIPTION

In the following detailed description, for purposes of explanation and not limitation, example embodiments disclosing specific details are set forth in order to provide a thorough understanding of the present teachings. However, it will be apparent to one having ordinary skill in the art having the benefit of the present disclosure that other embodiments according to the present teachings that depart from the specific details disclosed herein remain within the scope of the appended claims. Moreover, descriptions of well-known apparatuses and methods may be omitted so as to not obscure the description of the example embodiments. Such methods and apparatuses are clearly within the scope of the present teachings.

The terminology used herein is for purposes of describing particular embodiments only, and is not intended to be limiting. The defined terms are in addition to the technical, scientific, or ordinary meanings of the defined terms as commonly understood and accepted in the relevant context.

As used in the specification and appended claims, the terms ‘a’, ‘an’ and ‘the’ include both singular and plural referents, unless the context clearly dictates otherwise. Thus, for example, ‘a device’ includes one device and plural devices.

As used in the specification and appended claims, and in addition to their ordinary meanings, the terms ‘substantial’ or ‘substantially’ mean to with acceptable limits or degree. For example, ‘substantially cancelled’ means that one skilled in the art would consider the cancellation to be acceptable.

As used in the specification and the appended claims and in addition to its ordinary meaning, the term ‘approximately’ means to within an acceptable limit or amount to one having ordinary skill in the art. For example, ‘approximately the same’ means that one of ordinary skill in the art would consider the items being compared to be the same.

Relative terms, such as “above,” “below,” “top,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be “below” that element. Similarly, if the device were rotated by 90° with respect to the view in the drawings, an element described “above” or “below” another element would now be “adjacent” to the other element; where “adjacent” means either abutting the other element, or having one or more layers, materials, structures, etc., between the elements.

A variety of devices, structures thereof, materials and methods of fabrication are contemplated for the BAW resonators of the apparatuses of the present teachings. Various details of such devices and corresponding methods of fabrication may be found, for example, in one or more of the following U.S. patent publications: U.S. Pat. No. 6,107,721, to Lakin; U.S. Pat. Nos. 5,587,620, 5,873,153, 6,507,983, 7,388,454, 7,714,684, and 8,436,516 to Ruby et al.; U.S. Pat. Nos. 7,369,013, 7,791,434, and 8,230,562 to Fazzio, et al.; U.S. Pat. Nos. 8,188,810, 7,280,007, and 9,455,681 to Feng et al.; U.S. Pat. Nos. 8,248,185, and 8,902,023 to Choy, et al.; U.S. Pat. No. 7,345,410 to Grannen, et al.; U.S. Pat. No. 6,828,713 to Bradley, et al.; U.S. Pat. Nos. 7,561,009, 7,358,831, 9,243,316 to Larson, III et al.; U.S. Pat. No. 9,197,185 to Zou, et al., U.S. Patent Application Publication No. 20120326807 to Choy, et al.; U.S. Pat. No. 7,629,865 to Ruby; U.S. Patent Application Publications Nos. 20110180391, and 20120177816 to Larson III, et al.; U.S. Patent Application No. 20140132117 to Larson III; U.S. Patent Application Publication No. 20070205850 to Jamneala et al.; U.S. Patent Application Publication No. 20110266925 to Ruby, et al. U.S. Patent Application Publication No. 20130015747 to Ruby, et al.; U.S. Patent Application Publication No. 20130049545 to Zou, et al.; U.S. Patent Application Publication No. 20140225682 to Burak, et al.; U.S. Patent Publication Nos.: 20140118090 and 20140354109 to Grannen, et al.; U.S. Patent Application Publication Nos. 20140292150, and 20140175950 to Zou, et al.; U.S. Patent Application Publication No. 20150244347 to Feng, et al.; U.S. Patent Application Publication 20150311046 to Yeh, et al.; and U.S. Patent Application Publication 20150207489 to Bi, et al. The entire disclosure of each of the patents, and patent application publications listed above are hereby specifically incorporated by reference herein. It is emphasized that the components, materials and methods of fabrication described in these patents and patent applications are representative, and other methods of fabrication and materials within the purview of one of ordinary skill in the art are also contemplated.

The described embodiments relate generally to bulk acoustic wave (BAW) resonators. Generally, the BAW resonators comprise a first electrode; a second electrode; and a piezoelectric layer disposed between the first and second electrodes. The piezoelectric layer comprises a piezoelectric material doped to a minimum atomic percentage with at least one rare earth element. In a representative embodiment, the BAW resonators comprise a first buffer layer disposed over the first electrode; and a second buffer layer disposed over the first piezoelectric layer. In a representative embodiment, the first buffer layer, or the second buffer layer, or both, are doped with the at least one rare earth element to an atomic percentage that is less than the minimum percentage. Notably, the first and second buffer layers are not necessarily doped with the same rare-earth element, or are not both doped to the same atomic percentage of dopant, or both.

In another representative embodiment, the BAW resonators comprise a buffer layer disposed over the piezoelectric layer, and beneath the second electrode. Again, the piezoelectric layer comprises a piezoelectric material doped to a minimum atomic percentage with at least one rare earth element; and the buffer layer is doped with the at least one rare earth element to an atomic percentage that is less than the minimum percentage.

When percentages of doping elements in a piezoelectric layer or a buffer layer are discussed herein, it is in reference to the total atoms of the piezoelectric layer. Notably, when the percentages of doping elements (e.g., Sc) in a doped AlN layer are discussed herein, it is in reference to the total atoms (including nitrogen) of the AlN piezoelectric layer. So, for example, and as described for example in U.S. Patent Application Publication No. 20140132117, if the Sc in the piezoelectric layer of a representative embodiment has an atomic percentage of approximately 5.0%, and the Al has an atomic percentage of approximately 95.0%, then the atomic consistency of the piezoelectric layer may then be represented as Al_{0.95}Sc_{0.05} N.

In certain embodiments described in more detail below, the piezoelectric layer comprises aluminum nitride (AlN) that is doped with scandium (Sc). The atomic percentage of scandium in an aluminum nitride layer is approximately greater than 9.0% to approximately 44.0%; and in other representative embodiments, the percentage of scandium in an aluminum nitride layer is approximately greater than 5.0% to approximately 44.0%. In such embodiments, and as described more fully below, in embodiments with two buffer layers, each buffer layer also comprises AlN, and one or both of the first and second buffer layers is doped with scandium to an atomic percentage less than that of the Sc-doped AlN layer. Specifically, in certain representative embodiments, one or both of the first and second buffer layers is doped with scandium to an atomic percentage in the range of approximately 0.0% to less than 9.0%; and in other representative embodiments one or both of the first and second buffer layers is doped with scandium to an atomic percentage in the range of approximately 0.0% to less than approximately 5.0%. As noted above, the atomic doping levels (atomic percentages) of scandium in the first and second AlN buffer layers are not necessarily the same. In other embodiments described below, only one AlN buffer layer is provided directly on top of the piezoelectric layer. This buffer layer is doped with scandium to an atomic percentage less than the atomic doping level of the Sc-doped AlN layer.

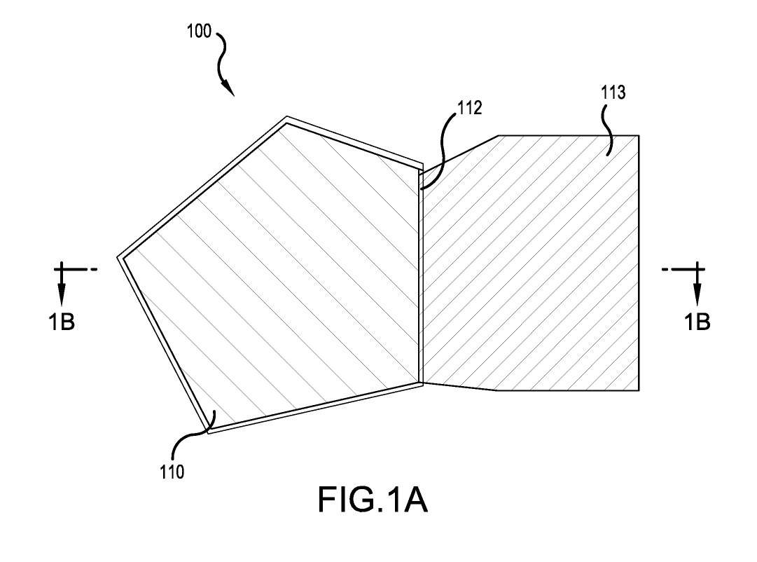

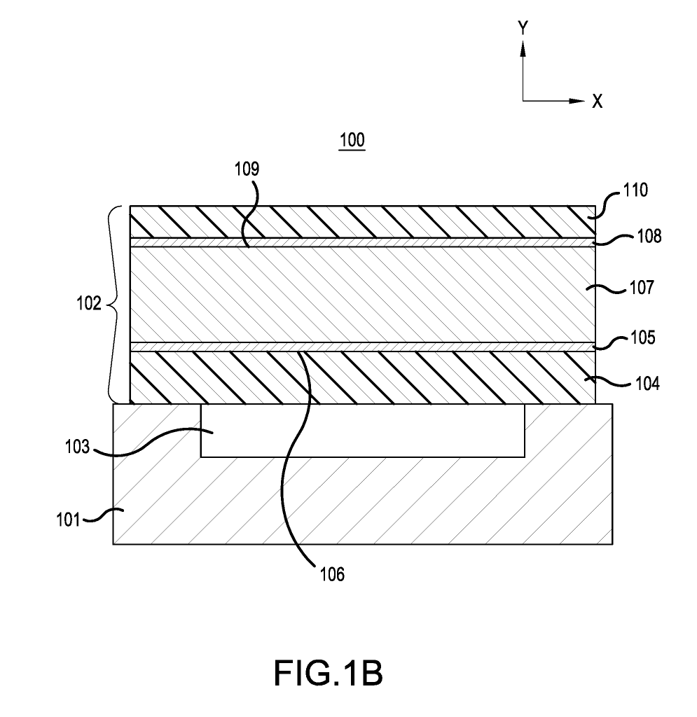

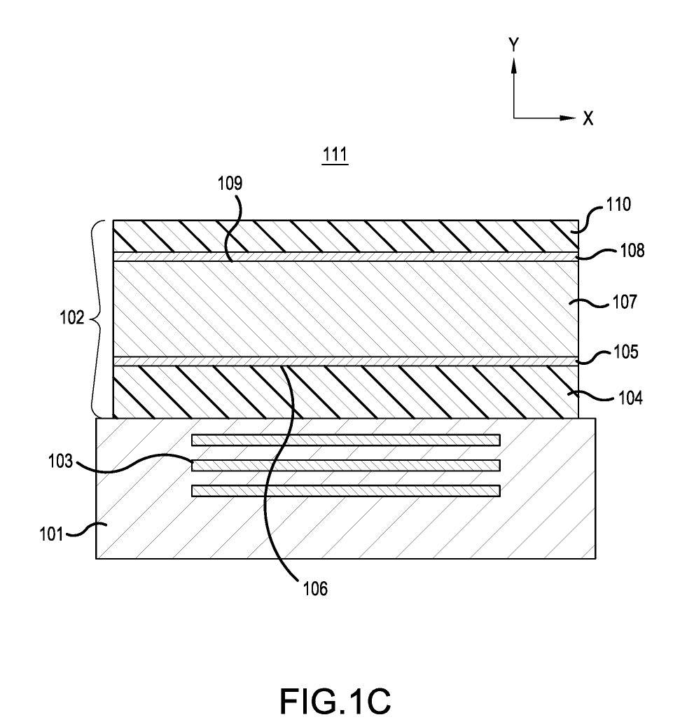

FIG. 1A is a top view of a BAW resonator 100 in accordance with a representative embodiment. The BAW resonator 100 comprises an upper electrode 110 (referred to below as second electrode 110) illustratively having five (5) sides, with a connection side 112 configured to provide an electrical connection to interconnect 113. The interconnect 113 provides electrical signals to the upper electrode 110 to excite desired acoustic waves in a piezoelectric layer (not shown in FIG. 1) of the BAW resonator 100. Notably, an airbridge (not shown), such as described in above incorporated U.S. Pat. No. 8,248,185 may be provided at the connection side 112, and cantilevered portions (not shown), such as described in above-incorporated U.S. Pat. No. 8,902,023 may be provided on one or more of the sides, other than the connection side 112. Notably, the configuration of the structure depicted in FIG. 1A is merely illustrative, and many other configurations such as described in the above-incorporated patents and patent application publications are contemplated for use in connection with the BAW resonators of the present teachings.

FIG. 1B is a cross-sectional view of BAW resonator 100 along the line 1B-1B, according to a representative embodiment. The BAW resonator 100 comprises a substrate 101, with an acoustic stack 102 disposed over a reflective element 103, which, in the present representative embodiment, is a cavity provided in the substrate 101. The acoustic stack comprises: a first electrode 104 disposed over the substrate 101; a first buffer layer 105 disposed over an upper surface 106 of the first electrode 104; a piezoelectric layer 107 is disposed over the first buffer layer 105; and a second buffer layer 108 is disposed over an upper surface 109 of the piezoelectric layer 107; and a second electrode 110 is disposed over the second buffer layer 108.

As described in certain patents and patent application publications incorporated by reference above, an overlap of the acoustic stack 102 with the reflective element 103 is referred to as the active area. Moreover, when the reflective element 103 is a cavity or void beneath the first electrode, the BAW resonator 100 is often referred to as an FBAR. By contrast, as described below, the reflective element 103 may comprise a Bragg reflector, which comprises alternating layers of high acoustic impedance material and low acoustic impedance material. When the reflective element 103 comprises a Bragg reflector, the BAW resonator 100 is often referred to as an SMR.

In representative embodiments, the first and second electrodes illustratively comprise molybdenum (Mo), and the substrate 101 comprises silicon (Si). These materials are merely illustrative, and it is emphasized that other materials, such as disclosed in the above-incorporated patents and patent application publications, are contemplated.

The piezoelectric layer 107 comprises a highly-textured, doped piezoelectric material, and may be formed using a known method, such as described in above-incorporated U.S. Pat. No. 9,455,681, and U.S. Patent Publications 20140132117 and 20150311046. Various embodiments relate to providing a thin film of piezoelectric material (e.g., piezoelectric layer 107), with an enhanced piezoelectric coefficient d₃₃ and an enhanced electromechanical coupling coefficient kt² by incorporating one or more rare earth elements into the crystal lattice of a portion of the piezoelectric layer. By incorporating specific atomic percentages of the multiple rare earth elements, the piezoelectric properties of the piezoelectric material, including piezoelectric coefficient d₃₃ and enhanced electromechanical effective coupling coefficient kt², are improved as compared to the same piezoelectric material that is entirely stoichiometric (undoped).

In accordance with a representative embodiment, the piezoelectric layer 107 comprises AlN material doped with scandium (Sc), for example, creating an AlScN compound with a predetermined atomic percentage of Sc. The Sc atom has an atomic radius that is larger than the atomic radius of the Al atom, resulting in an Sc—N bond length (2.25 Å) that is greater than the Al—N bond length (1.90 Å). This difference in bond lengths causes stress in the resulting AlScN material. As such, electric dipoles of the piezoelectric material of piezoelectric layer 107 are altered in such a way that an electrical field produces a comparatively strong mechanical response of the dipoles, resulting in a higher kt². As noted above, the atomic percentage of scandium in the aluminum nitride layer (i.e., the atomic percent of Sc in Sc—Al inside the Al—Sc—N material) is greater than approximately 9.0% to approximately 44.0%; and in other representative embodiments, the percentage of scandium in an aluminum nitride layer is approximately greater than approximately 5.0% to approximately 44.0%

Alternatively, a number of Al atoms within the AlN crystal lattice may be replaced with other rare earth element(s) at predetermined percentages. The rare earth elements include yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb) and lutetium (Lu), as known by one of ordinary skill in the art. The various embodiments contemplate incorporation of any one or more rare earth elements, although specific examples are discussed herein. Because the doping elements replace only Al atoms in the AlN crystal, the percentage of nitrogen atoms in the piezoelectric material remains substantially the same regardless of the amount of doping. As such, and as noted above, when percentages of doping elements are discussed herein, it is in reference to the total atoms (including nitrogen) of the AlN piezoelectric material.

In certain known piezoelectric layers that are doped to an atomic percentage of Sc at atomic doping levels greater than approximately 5%, the incidence of embedded bulk defects increases. These bulk defects are comprised of “clustered” scandium atoms in the crystalline structure of aluminum nitride, and result in concentrations of scandium atoms that are greater than the desired concentration of scandium dopants in the piezoelectric layer. These bulk defects can have a deleterious impact on desired characteristics of the piezoelectric material, and on BAW resonators comprising such piezoelectric material. Just by way of example, the acoustic coupling coefficient (kt²) can vary significantly across the wafer when the doped piezoelectric layer has a significant number of bulk defects. Similarly, other parameters, such as the resistance at parallel resonance (Rₚ) and the overall quality factors of BAW resonators made from such a wafer can vary significantly as well. As can be appreciated, such variability of material and device parameters across a wafer comprising many BAW resonators is unacceptable.

Applicants have discovered that by providing the first buffer layer 105 over the upper surface 106 of the first electrode 104, the variability of the noted parameters across a wafer is significantly reduced. While not wishing to be bound by theory, Applicants believe that providing the first buffer layer 105 provides a good lattice structure over which the piezoelectric layer 107 can be grown. This results in suppression of the noted bulk (embedded) defects in the resultant piezoelectric layer, and a more uniform piezoelectric layer 107 with fewer incidents of clustering of Sc dopants, and a significant reduction in bulk defects caused by Sc dopants. Just by way of example, Applicants have realized a reduction in defects using a known surface scanning technique over an upper surface of a known Sc doped AlN layer from approximately 30,000 counts on a 150 mm wafer, to approximately 300 counts to approximately 500 counts over upper surface 109 of piezoelectric layer 107 of a representative embodiment. As a result of the reduction in embedded defects in the piezoelectric layer 107 grown over the first buffer layer 105, and a more uniform piezoelectric layer 107, the variation of the acoustic coupling coefficient (kt²) is reduced by approximately 600% across a 150 mm wafer.

The first buffer layer 105 is highly textured to provide a good crystalline surface on which the piezoelectric layer 107 is grown. Illustratively, the first buffer layer 105 has a thickness in the range of approximately 30 Å to approximately 300 Å.

Like the piezoelectric layer 107, the first buffer layer 105 is formed over the upper surface 106 of the first electrode 104 using a known method, such as those described above-incorporated U.S. Pat. No. 9,455,681, and U.S. Patent Publications 20140132117, and 20150311046. The first buffer layer 105 may include the same dopant (e.g., Sc) as provided in subsequently formed piezoelectric layer 107, or may be undoped. However, the atomic doping level in the first buffer layer 105 is often significantly less than the atomic doping level in the piezoelectric layer 107. Illustratively, the atomic doping level of scandium in the first buffer layer 105 is in the range of less than approximately 9.0% (atomic percent) to approximately 0% (i.e., undoped); and, in some representative embodiments, the atomic doping level of scandium in the first buffer layer 105 is in the range of less than approximately 5.0% (atomic percent) to approximately 0% (i.e., undoped). As alluded to above, providing first buffer layer 105 that is either undoped, or doped to less than the doping percentage of the piezoelectric layer 107 fosters formation of a good lattice structure over which the piezoelectric layer 107 can be formed, thereby resulting in a significant reduction in bulk defects in the resultant piezoelectric layer 107 compared to known acoustic stacks.

In addition to an unacceptable level of bulk defects, in certain known piezoelectric layers that are doped to an atomic percentage of Sc at atomic doping levels greater than approximately 5%, the roughness of the upper surface 109 can be problematic. To this end, with increasing atomic doping levels of the piezoelectric layer 107, the roughness of the upper surface 109 increases. When the roughness of the upper surface 109 is too great, acoustic reflections are inefficient and result in loss of acoustic energy. These acoustic losses are viscous losses (also known as acoustic losses at an interface) that can deleteriously impact device performance. By way of example, viscous losses adversely impact the acoustic coupling, and thereby the acoustic coupling coefficient (kt²) of the piezoelectric layer, as well as the overall quality factor (Q) of the BAW device incorporating such a piezoelectric layer.

Applicants have discovered that by providing the second buffer layer 108 over the upper surface 109 of the piezoelectric layer, an overall increase in the acoustic coupling coefficient (kt²), and its attendant parameters, resistance at parallel resonance (Rp), and resistance at series resonance (Rs) are realized. Similarly, the overall Q of the device is increased.

As depicted in FIG. 1B, the second buffer layer 108 is formed over the upper surface 109 of the piezoelectric layer 107 using a known method, such as those described above-incorporated U.S. Pat. No. 9,455,681, and U.S. Patent Publications 20140132117, and 20150311046. The second buffer layer 108 may include the same dopant (e.g., Sc) as provided in subsequently formed piezoelectric layer 107, or may be undoped. However, the atomic doping level in the second buffer layer 108 is often significantly less than the atomic doping level in the piezoelectric layer 107. Illustratively, the atomic doping level of scandium in the first buffer layer 105 is in the range of less than approximately 9.0% (atomic percent) to approximately 0% (i.e., undoped); and, in some representative embodiments, the atomic doping level of scandium in the first buffer layer 105 is in the range of less than approximately 5.0% (atomic percent) to approximately 0% (i.e., undoped).

As alluded to above, and again while not wishing to be bound to theory, Applicants believe that providing a highly textured second buffer layer 108, a more planar/smoother surface is provided over which to deposit the second electrode 110. To this end, in a representative embodiment, the second buffer layer 108 is AlN, that has an atomic doping level less than that of the piezoelectric layer 107. By being lightly doped, or even undoped, the second buffer layer 108 provides the comparatively smooth and planar upper surface 109 on which the second electrode is disposed. The comparatively smooth and planar upper surface 109 does not contribute to undesired interfacial acoustic reflections, and thereby improves viscous losses compared to an acoustic stack that has a comparatively highly doped piezoelectric layer (with a comparatively rough upper surface) on which the second electrode is directly disposed. By way of example, in accordance with a representative embodiment, the acoustic coupling coefficient (kt²) of the piezoelectric layer 107 of a representative embodiment shows improvement over known piezoelectric layers without the second buffer layer 108 of approximately 30% or more; in absolute numbers known AlN piezoelectric layers doped within the noted range with Sc provide an acoustic coupling coefficient of approximately 10.9, whereas the acoustic coupling coefficient of Sc-doped AlN piezoelectric layer 107 with the second buffer layer 108 thereover, is in the range of approximately 11.1 to approximately 11.3.

FIG. 1C is a cross-sectional view of BAW resonator 111, according to a representative embodiment. The BAW resonator 111 comprises substrate 101, with acoustic stack 102 disposed over a reflective element 103, which, in the present representative embodiment, is a Bragg reflector, which comprises alternating layers of high acoustic impedance material and low acoustic impedance material. As such, the BAW resonator 111 is an SMR.

The acoustic stack 102 comprises: first electrode 104 disposed over the substrate 101; first buffer layer 105 disposed over an upper surface 106 of the first electrode 104; piezoelectric layer 107 disposed over the first buffer layer 105; second buffer layer 108 is disposed over upper surface 109 of the piezoelectric layer 107; and second electrode 110 is disposed over the second buffer layer 108.

As described above, in representative embodiments, the first and second electrodes illustratively comprise molybdenum (Mo), and the substrate 101 comprises silicon (Si). These materials are merely illustrative, and it is emphasized that other materials, such as disclosed in the above-incorporated patents and patent application publications, are contemplated.

The piezoelectric layer 107 comprises a highly-textured, doped piezoelectric material, and may be formed using a known method, such as described in above-incorporated U.S. Pat. No. 9,455,681, and U.S. Patent Publications 20140132117 and 20150311046. Various embodiments relate to providing a thin film of piezoelectric material (e.g., piezoelectric layer 107), with an enhanced piezoelectric coefficient d₃₃ and an enhanced electromechanical coupling coefficient kt² by incorporating one or more rare earth elements into the crystal lattice of a portion of the piezoelectric layer. By incorporating specific atomic percentages of the multiple rare earth elements, the piezoelectric properties of the piezoelectric material, including piezoelectric coefficient d₃₃ and enhanced electromechanical effective coupling coefficient kt², are improved as compared to the same piezoelectric material that is entirely stoichiometric (undoped).

In accordance with a representative embodiment, the piezoelectric layer 107 comprises AlN material doped with scandium (Sc), for example, creating an AlScN compound with a predetermined atomic percentage of Sc. The Sc atom has an atomic radius that is larger than the atomic radius of the Al atom, resulting in an Sc—N bond length (2.25 Å) that is greater than the Al—N bond length (1.90 Å). This difference in bond lengths causes stress in the resulting AlScN material. As such, electric dipoles of the piezoelectric material of piezoelectric layer 107 are altered in such a way that the electrical field produces a comparatively strong mechanical response of the dipoles, resulting in a higher kt². As noted above, in certain representative embodiments, the atomic percentage of scandium in the aluminum nitride layer (i.e., the atomic percent of Sc in Sc—Al inside the Al—Sc—N material) is greater than approximately 9.0% to approximately 44.0%; and in other representative embodiments, the atomic percentage of scandium in the aluminum nitride layer (i.e., the atomic percent of Sc in Sc—Al inside the Al—Sc—N material) is greater than approximately 5.0% to approximately 44.0%.

Alternatively, a number of Al atoms within the AlN crystal lattice may be replaced with other rare earth element(s) at predetermined percentages. The rare earth elements include yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb) and lutetium (Lu), as known by one of ordinary skill in the art. The various embodiments contemplate incorporation of any one or more rare earth elements, although specific examples are discussed herein. Because the doping elements replace only Al atoms in the AlN crystal, the percentage of nitrogen atoms in the piezoelectric material remains substantially the same regardless of the amount of doping. As such, and as noted above, when percentages of doping elements are discussed herein, it is in reference to the total atoms (including nitrogen) of the AlN piezoelectric material.

In certain known piezoelectric layers that are doped to an atomic percentage of Sc at atomic doping levels greater than approximately 5%, the incidence of bulk defects increases. As described above, these bulk defects are comprised of “clustered” scandium atoms in the crystalline structure of aluminum nitride, and result in concentrations of scandium atoms that are greater than the desired concentration of scandium dopants in the piezoelectric layer. These bulk defects can have a deleterious impact on desired characteristics of the piezoelectric material, and on BAW resonators comprising such piezoelectric material. Just by way of example, the acoustic coupling coefficient (kt²) can vary significantly across the wafer when the doped piezoelectric layer has a significant number of bulk defects. Similarly, other parameters, such as the resistance at parallel resonance (Rₚ) and the overall quality factors of BAW resonators made from such a wafer can vary significantly as well. As can be appreciated, such variability of material and device parameters across a wafer comprising many BAW resonators is unacceptable.

Applicants have discovered that by providing the first buffer layer 105 over the upper surface 106 of the first electrode 104, the variability of the noted parameters across a wafer is significantly reduced. While not wishing to be bound by theory, Applicants believe that providing the first buffer layer 105 provides a good lattice structure over which the piezoelectric layer 107 can be grown. This results in suppression of the noted bulk (embedded) defects in the resultant piezoelectric layer, and a more uniform piezoelectric layer 107 with fewer incidents of clustering of Sc dopants, and a significant reduction in bulk defects caused by Sc dopants. Just by way of example, Applicants have realized a reduction in defects using a known surface scanning technique over an upper surface of a known Sc doped AlN layer from approximately 30,000 counts on a 150 mm wafer, to approximately 300 counts to approximately 500 counts over upper surface 109 of piezoelectric layer 107 of a representative embodiment. As a result of the reduction in embedded defects in the piezoelectric layer 107 grown over the first buffer layer 105, and a more uniform piezoelectric layer 107, the variation of the acoustic coupling coefficient (kt²) is reduced by approximately 600% across a 150 mm wafer.

The first buffer layer 105 is highly textured to provide a good crystalline surface on which the piezoelectric layer 107 is grown. Like the piezoelectric layer 107, the first buffer layer 105 is formed over the upper surface 106 of the first electrode 104 using a known method, such as those described above incorporated U.S. Pat. No. 9,455,681, and U.S. Patent Publications 20140132117, and 20150311046. The first buffer layer 105 may include the same dopant (e.g., Sc) as provided in subsequently formed piezoelectric layer 107, or may be undoped. However, the atomic doping level in the first buffer layer 105 is often significantly less than the atomic doping level in the piezoelectric layer 107. Illustratively, in certain representative embodiments, the atomic doping level of scandium in the first buffer layer 105 is in the range of less than approximately 9.0% (atomic percent) to approximately 0% (i.e., undoped); and in other representative embodiments, the atomic doping level of scandium in the first buffer layer 105 is in the range of less than approximately 5.0% (atomic percent) to 0% (i.e., undoped). As described above, providing first buffer layer 105 that is that is either undoped, or doped to less than the atomic doping level of the piezoelectric layer 107 fosters formation of a good lattice structure over which the piezoelectric layer 107 can be formed, thereby resulting in a significant reduction in bulk defects in the resultant piezoelectric layer 107 compared to known acoustic stacks.

In addition to an unacceptable level of bulk defects, in certain known piezoelectric layers that are doped to an atomic percentage of Sc at atomic doping levels greater than approximately 9%, the roughness of the upper surface 109 can be problematic. To this end, with increasing atomic doping levels of the piezoelectric layer 107, the roughness of the upper surface 109 increases. When the roughness of the upper surface 109 is too great, acoustic reflections are inefficient and result in loss of acoustic energy. These acoustic losses are viscous losses (also known as acoustic losses at an interface) can deleteriously impact device performance. By way of example, viscous losses adversely impact the acoustic coupling, and thereby the acoustic coupling coefficient (kt²) of the piezoelectric layer, as well as the overall quality factor (Q) of the BAW device incorporating such a piezoelectric layer.

Applicants have discovered that by providing the second buffer layer 108 over the upper surface 109 of the piezoelectric layer, an overall increase in the acoustic coupling coefficient (kt²), and its attendant parameters, resistance at parallel resonance (Rp), and resistance at series resonance (Rs) are realized. Similarly, the overall Q of the device is increased. Again, while not wishing to be bound to theory, Applicants believe that providing a highly textured second buffer layer 108, a more planar/smoother surface is provided over which to deposit the second electrode 110. To this end, in a representative embodiment, the second buffer layer 108 is AlN, that has an atomic doping level in the ranges of less than that of the doped piezoelectric layer 107. By being lightly doped, or even undoped, the second buffer layer 108 provides the comparatively smooth and planar upper surface 109 on which the second electrode in disposed. The comparatively smooth and planar upper surface 109 does not contribute to undesired interfacial acoustic reflections, and thereby improves viscous losses compared to an acoustic stack that had a comparatively highly doped piezoelectric layer (with a comparatively rough upper surface) on which the second electrode is directly disposed. By way of example, in accordance with a representative embodiment, the acoustic coupling coefficient (kt²) of the piezoelectric layer 107 of a representative embodiment shows improvement over known piezoelectric layers without the second buffer layer 108 of approximately 30% or more; in absolute numbers known AlN piezoelectric layers doped within the noted range with Sc provide an acoustic coupling coefficient of approximately 10.9, whereas the acoustic coupling coefficient of Sc-doped AlN piezoelectric layer 107 with the second buffer layer 108 thereover, is in the range of approximately 11.1 to approximately 11.3.

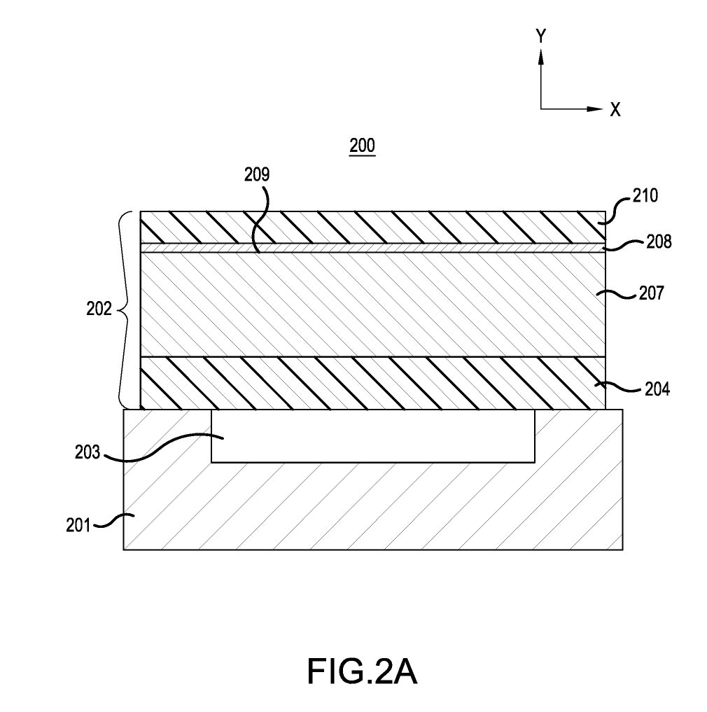

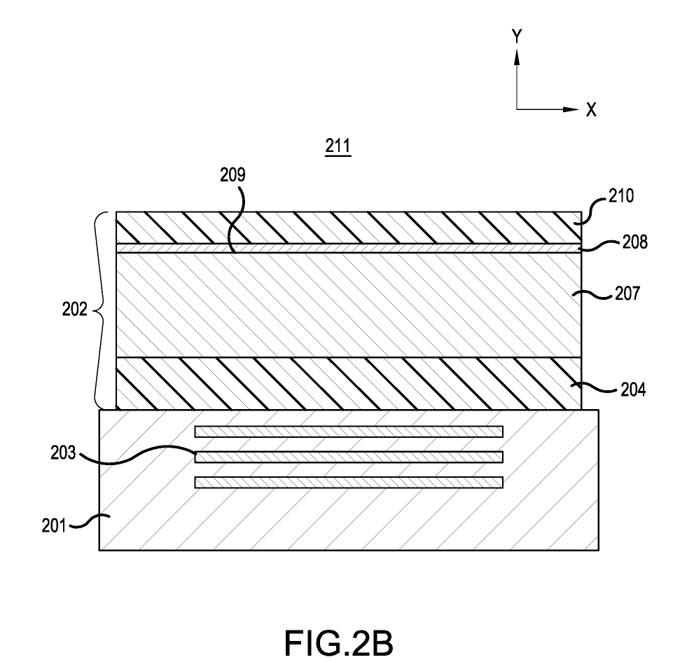

FIG. 2A is a cross-sectional view of BAW resonator 200, according to a representative embodiment. Many aspects and details of the BAW resonator 200 are common to BAW resonator 100 described above. Common aspects and details may not be repeated.

The BAW resonator 200 comprises a substrate 201, with an acoustic stack 202 disposed over a reflective element 203, which, in the present representative embodiment, is a cavity provided in the substrate 201. The acoustic stack comprises a first electrode 204 disposed over the substrate 201, a piezoelectric layer 207 disposed over the first electrode 204, and a buffer layer 208 is disposed over an upper surface 209 of the piezoelectric layer 207. A second electrode 210 is disposed over the buffer layer 208.

As noted above, because the reflective element 203 is a cavity or void beneath the first electrode 204, the BAW resonator 200 is often referred to as an FBAR.

In representative embodiments, the first and second electrodes illustratively comprise molybdenum (Mo), and the substrate 201 comprises silicon (Si). These materials are merely illustrative, and it is emphasized that other materials, such as disclosed in the above-incorporated patents and patent application publications, are contemplated.

The piezoelectric layer 207 comprises a highly-textured, doped piezoelectric material, and may be formed using a known method, such as described in above-incorporated U.S. Pat. No. 9,455,681, and U.S. Patent Publications 20140132117 and 20150311046. Various embodiments relate to providing a thin film of piezoelectric material (e.g., piezoelectric layer 207), with an enhanced piezoelectric coefficient d₃₃ and an enhanced electromechanical coupling coefficient kt² by incorporating one or more rare earth elements into the crystal lattice of a portion of the piezoelectric layer. By incorporating specific atomic percentages of the multiple rare earth elements, the piezoelectric properties of the piezoelectric material, including piezoelectric coefficient d₃₃ and enhanced electromechanical effective coupling coefficient kt², are improved as compared to the same piezoelectric material that is entirely stoichiometric (undoped).

In accordance with a representative embodiment, the piezoelectric layer 207 comprises AlN material doped with scandium (Sc), for example, creating an AlScN compound with a predetermined atomic percentage of Sc. The Sc atom has an atomic radius that is larger than the atomic radius of the Al atom, resulting in an Sc—N bond length (2.25 Å) that is greater than the Al—N bond length (1.90 Å). This difference in bond lengths causes stress in the resulting AlScN material. As such, electric dipoles of the piezoelectric material of piezoelectric layer 207 are altered in such way that electrical field produces a comparatively strong mechanical response of the dipoles, resulting in a higher kt². As noted above, the atomic percentage of scandium in the aluminum nitride layer (i.e., the atomic percent of Sc in Sc—Al inside the Al—Sc—N material) is greater than approximately 9.0% to approximately 44.0%; and in other representative embodiments, the atomic percentage of scandium in the aluminum nitride layer (i.e., the atomic percent of Sc in Sc—Al inside the Al—Sc—N material) is greater than approximately 5.0% to approximately 44.0%.

As can be appreciated from a review of FIG. 2A, BAW resonator 200 includes only the buffer layer 208 disposed over the upper surface 209 of the piezoelectric layer 207. As noted above, in certain known piezoelectric layers that are doped to an atomic percentage of Sc at atomic doping levels greater than approximately 5%, the roughness of the upper surface 209 can be problematic. To this end, with increasing atomic doping levels of the piezoelectric layer 107, the roughness of the upper surface 109 increases. When the roughness of the upper surface 209 is too great, acoustic reflections are inefficient and result in loss of acoustic energy. These acoustic losses are viscous losses (also known as acoustic losses at an interface) and can deleteriously impact device performance. By way of example, viscous losses adversely impact the acoustic coupling, and thereby the acoustic coupling coefficient (kt²) of the piezoelectric layer, as well as the overall quality factor (Q) of the BAW device incorporating such a piezoelectric layer.

Applicants have discovered that by providing the buffer layer 208 over the upper surface 209 of the piezoelectric layer, an overall increase in the acoustic coupling coefficient (kt²), and its attendant parameters, resistance at parallel resonance (Rp), and resistance at series resonance (Rs) are realized. Similarly, the overall Q of the device is increased. Again, while not wishing to be bound to theory, Applicants believe that providing a highly textured buffer layer 208, a more planar/smoother surface is provided over which to deposit the second electrode 210. To this end, in a representative embodiment, the buffer layer 208 is AlN, that has an atomic doping level less than the atomic doping level of the piezoelectric layer 207. By being lightly doped, or even undoped, the buffer layer 208 provides the comparatively smooth and planar upper surface 209 on which the second electrode in disposed. The comparatively smooth and planar upper surface 209 does not contribute to undesired interfacial acoustic reflections, and thereby improves viscous losses compared to an acoustic stack that had a comparatively highly doped piezoelectric layer (with a comparatively rough upper surface) on which the second electrode is directly disposed. By way of example, in accordance with a representative embodiment, the acoustic coupling coefficient (kt²) of the piezoelectric layer 207 of a representative embodiment shows improvement over known piezoelectric layers without the buffer layer 208 of approximately 30% or more; in absolute numbers known AlN piezoelectric layers doped within the noted range with Sc provide an acoustic coupling coefficient of approximately 10.9, whereas the acoustic coupling coefficient of Sc-doped AlN piezoelectric layer 107 with the second buffer layer 108 thereover, is in the range of approximately 11.1 to approximately 11.3.

FIG. 2B is a cross-sectional view of BAW resonator 211, according to a representative embodiment. The BAW resonator 211 comprises substrate 201, with acoustic stack 202 disposed over a reflective element 203, which, in the present representative embodiment, is a Bragg reflector, which comprises alternating layers of high acoustic impedance material and low acoustic impedance material. As such, the BAW resonator 211 is an SMR. Many aspects and details of the BAW resonator 211 are common to BAW resonator 200 described above. Common aspects and details may not be repeated.

In representative embodiments, the first and second electrodes illustratively comprise molybdenum (Mo), and the substrate 201 comprises silicon (Si). These materials are merely illustrative, and it is emphasized that other materials, such as disclosed in the above-incorporated patents and patent application publications, are contemplated.

The piezoelectric layer 207 comprises a highly-textured, doped piezoelectric material, and may be formed using a known method, such as described in above-incorporated U.S. Pat. No. 9,455,681, and U.S. Patent Publications 20140132117 and 20150311046. Various embodiments relate to providing a thin film of piezoelectric material (e.g., piezoelectric layer 207), with an enhanced piezoelectric coefficient d₃₃ and an enhanced electromechanical coupling coefficient kt² by incorporating one or more rare earth elements into the crystal lattice of a portion of the piezoelectric layer. By incorporating specific atomic percentages of the multiple rare earth elements, the piezoelectric properties of the piezoelectric material, including piezoelectric coefficient d₃₃ and enhanced electromechanical effective coupling coefficient kt², are improved as compared to the same piezoelectric material that is entirely stoichiometric (undoped).

In accordance with a representative embodiment, the piezoelectric layer 207 comprises AlN material doped with scandium (Sc), for example, creating an AlScN compound with a predetermined atomic percentage of Sc. The Sc atom has an atomic radius that is larger than the atomic radius of the Al atom, resulting in an Sc—N bond length (2.25 Å) that is greater than the Al—N bond length (1.90 Å). This difference in bond lengths causes stress in the resulting AlScN material. As such, electric dipoles of the piezoelectric material of piezoelectric layer 207 are altered in such way that electrical field produces a comparatively strong mechanical response of the dipoles, resulting in a higher kt². As noted above, in certain embodiments, the atomic percentage of scandium in the aluminum nitride layer (i.e., the atomic percent of Sc in Sc—Al inside the Al—Sc—N material) is greater than approximately 9.0% to approximately 44.0%; and in other representative embodiments, the atomic percentage of scandium in the aluminum nitride layer (i.e., the atomic percent of Sc in Sc—Al inside the Al—Sc—N material) is greater than approximately 5.0% to approximately 44.0%.

As can be appreciated from a review of FIG. 2A, BAW resonator 200 includes only the buffer layer 208 disposed over the upper surface 209 of the piezoelectric layer 207. As noted above, in certain known piezoelectric layers that are doped to an atomic percentage of Sc at atomic doping levels greater than approximately 5%, the roughness of the upper surface 209 can be problematic. To this end, with increasing atomic doping levels of the piezoelectric layer 107, the roughness of the upper surface 209 increases. When the roughness of the upper surface is too great, acoustic reflections are inefficient and result in loss of acoustic energy. These acoustic losses are viscous losses (also known as acoustic losses at an interface) and can deleteriously impact device performance. By way of example, viscous losses adversely impact the acoustic coupling, and thereby the acoustic coupling coefficient (kt²) of the piezoelectric layer, as well as the overall quality factor (Q) of the BAW device incorporating such a piezoelectric layer.

Applicants have discovered that by providing the buffer layer 208 over the upper surface 209 of the piezoelectric layer, an overall increase in the acoustic coupling coefficient (kt²), and its attendant parameters, resistance at parallel resonance (Rp), and resistance at series resonance (Rs) are realized. Similarly, the overall Q of the device is increased. Again, while not wishing to be bound to theory, Applicants believe that providing a highly textured buffer layer 208, a more planar/smoother surface is provided over which to deposit the second electrode 210. To this end, in a representative embodiment, the buffer layer 208 is AlN, that has an atomic doping level that is less than the atomic doping level of the piezoelectric layer 207. By being lightly doped, or even undoped, the buffer layer 208 provides the comparatively smooth and planar upper surface 209 on which the second electrode in disposed. The comparatively smooth and planar upper surface 209 does not contribute to undesired interfacial acoustic reflections, and thereby improves viscous losses compared to an acoustic stack that had a comparatively highly doped piezoelectric layer (with a comparatively rough upper surface) on which the second electrode is directly disposed. By way of example, in accordance with a representative embodiment, the acoustic coupling coefficient (kt²) of the piezoelectric layer 207 of a representative embodiment shows improvement over known piezoelectric layers without the buffer layer 208 of approximately 30% or more; in absolute numbers known AlN piezoelectric layers doped within the noted range with Sc provide an acoustic coupling coefficient of approximately 10.9, whereas the acoustic coupling coefficient of Sc-doped AlN piezoelectric layer 107 with the second buffer layer 108 thereover, is in the range of approximately 11.1 to approximately 11.3.

In accordance with representative embodiments, BAW resonators comprising doped piezoelectric layers, a raised frame element, or a recessed frame element, or both, are described. One of ordinary skill in the art would appreciate that many variations that are in accordance with the present teachings are possible and remain within the scope of the appended claims. These and other variations would become clear to one of ordinary skill in the art after inspection of the specification, drawings and claims herein. The invention therefore is not to be restricted except within the spirit and scope of the appended claims.

1. A bulk acoustic wave (BAW) resonator, comprising:
a first electrode;
a first buffer layer disposed over the first electrode;
a piezoelectric layer disposed over the first buffer layer, the piezoelectric layer comprising a piezoelectric material doped to a minimum atomic percentage with at least one rare earth element;
a second buffer layer disposed over the piezoelectric layer; and
a second electrode disposed over the second buffer layer, wherein the first buffer layer, or the second buffer layer, or both, are doped with the at least one rare earth element to an atomic percentage that is less than the minimum atomic percentage.

2. The BAW resonator as claimed in claim 1, wherein piezoelectric material comprises aluminum nitride (AlN), the at least one rare earth element comprises scandium (Sc), and the minimum atomic percentage of Sc is greater than approximately 5.0%.

3. The BAW resonator as claimed in claim 2, wherein a maximum atomic percentage of Sc is approximately 44.0%.

4. The BAW resonator as claimed in claim 2, wherein the first buffer layer comprises AlN.

5. The BAW resonator as claimed in claim 4, wherein the first buffer layer is doped with Sc, and an atomic percentage of Sc in the first buffer layer is in the range of approximately 0.0% to less than approximately 9.0%.

6. The BAW resonator as claimed in claim 4, wherein the first buffer layer is doped with Sc, and an atomic percentage of Sc in the first buffer layer is in the range of approximately 0.0% to less than approximately 5.0%.

7. The BAW resonator as claimed in claim 4, wherein the first buffer layer has a thickness in the range of approximately 30 Å to approximately 300 Å.

8. The BAW resonator as claimed in claim 2, wherein the second buffer layer comprises AlN.

9. The BAW resonator as claimed in claim 8, wherein the second buffer layer is doped with Sc, and the atomic percentage of Sc in the second buffer layer is in the range of 0.0% to less than approximately 9.0%.

10. The BAW resonator as claimed in claim 8, wherein the first buffer layer is doped with Sc, and the atomic percentage of Sc in the second buffer layer is in the range of approximately 0.0% to less than approximately 5.0%.

11. The BAW resonator as claimed in claim 8, wherein the second buffer layer has a thickness in the range of approximately 30 Å to approximately 300 Å.

12. The BAW resonator as claimed in claim 1, further comprising a reflective element disposed beneath the first electrode, the second electrode, the piezoelectric layer and the first and second buffer layers, wherein an overlap of the first electrode, the second electrode, the piezoelectric layer and the first and second buffer layers, and the reflective element defines an active area of the BAW acoustic resonator.

13. An BAW resonator as claimed in claim 12, wherein the reflective element comprises a cavity disposed in a substrate over which the first electrode, the second electrode and the piezoelectric layer are disposed.

14. A BAW resonator as claimed in claim 12, wherein the reflective element comprises a plurality of layers having alternating high acoustic impedance and low acoustic impedance.

15. A bulk acoustic wave (BAW) resonator, comprising:
a first electrode;
a piezoelectric layer disposed over the first buffer layer, the piezoelectric layer comprising a piezoelectric material doped to a minimum atomic percentage with at least one rare earth element;
a buffer layer disposed over the first piezoelectric layer; and
a second electrode disposed over the buffer layer, wherein the buffer layer is doped with the at least one rare earth element to an atomic percentage that is less than the minimum atomic percentage.

16. The BAW resonator as claimed in claim 15, wherein piezoelectric material comprises aluminum nitride (AlN), the at least one rare earth element comprises scandium (Sc), and the minimum atomic percentage of Sc is greater than approximately 5.0%.

17. The BAW resonator as claimed in claim 16, wherein a maximum atomic percentage of Sc is approximately 44.0%.

18. The BAW resonator as claimed in claim 16, wherein the buffer layer comprises AlN.

19. The BAW resonator as claimed in claim 18, wherein the buffer layer is doped with Sc, and the atomic percentage of Sc in the buffer layer is in the range of 0.0% to less than approximately 9.0%.

20. The BAW resonator as claimed in claim 18, wherein the buffer layer is doped with Sc, and the atomic percentage of Sc in the buffer layer is in the range of approximately 0.0% to less than approximately 5.0%.

21. The BAW resonator as claimed in claim 18, wherein the buffer layer has a thickness in the range of approximately 30 Å to approximately 300 Å.
